(19) United States
(12) Patent Application Publication
(10) Pub. No.: US 2010/0040978 A1
(43) Pub. Date: Feb. 18, 2010

(54) PHOTOSENSITIVE LITHOGRAPHIC PRINTING PLATE MATERIAL

(75) Inventor: Toshiyuki Matsumura, Kanagawa (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA MEDICAL & GRAPHIC, INC., Tokyo (JP)

(21) Appl. No.: 12/522,300

(22) PCT Filed: Nov. 22, 2007
(86) PCT No.: PCT/JP2007/072649

§ 371 Date: Jul. 7, 2009

(30) Foreign Application Priority Data
Jan. 10, 2007 (JP) 2007-002238

(51) Int. Cl. G03F 7/004

(52) U.S. Cl. 430/286.1

(57) ABSTRACT

A lithographic printing plate material that is suitable for exposure with laser beams of 350 to 450 nm emission wavelength, being highly sensitive and excelling in developability. The lithographic printing plate material is a photosensitive lithographic printing plate material with a photosensitive layer containing (A) polymerization initiator, (B) compound having an ethylenic double bond, (C) sensitizing dye and (D) polymer binder, characterized in that the photosensitive layer contains, as polymerizable ethylenic double bond having compound (B), a reaction product obtained by reaction of (BM1) compound having in each molecule at least one polymerizable ethylenic double bond and one hydroxyl and (BM2) compound having in each molecule one secondary amino and one hydroxyl with (BM3) diisocyanate compound, wherein the ratio of BM1(mole)/BM2(mole) is in the range of 2.4 to 38.0.

### FIELD OF TECHNOLOGY

The present invention relates to a photosensitive lithographic printing plate material used in a computer-to-plate (hereinafter referred to as CTP) system, and particularly to a photosensitive lithographic printing plate material suitable for exposure employing laser light having a wavelength of 350 to 450 nm.

### TECHNICAL BACKGROUND

In recent years, a CTP system has been developed and put into practical use, which directly writes digital image data on a photosensitive lithographic printing plate material employing laser light in a process of manufacturing a printing plate for off-set printing.

In a printing field in which relatively high printing durability is required, a negative working photosensitive lithographic printing plate material is known which comprises a polymerizable photosensitive layer containing a polymerizable compound (see for example, Japanese Unexamined Patent Application Publication (hereinafter referred to as JP-A)) Nos. 1-105238 and 2-127404).

A photosensitive printing plate material capable of being imagewise exposed with laser having an emission wavelength from 390 to 430 nm is known, which improves a safelight property in view of handling.

A compact blue-violet laser of high output power emitting rays with a wavelength of from 390 to 430 nm can be easily obtained. A printing plate material adapted to this laser, which can be processed under room light, has been developed (see Patent Document 1 and 2).

There are known photosensitive lithographic printing plate materials comprising a specific biimidazole in a photosensitive layer, which improves safe light properties under yellow light (see for example, JP-A No. 2001-194782). Further there are known light polymerizable composition comprising a hexaarylbiimidazole having an aryl group containing substitute of alkyl group as a high sensitive and low sublime polymerizable composition described in JP-A No. 2004-137152.

As a polymerizable compound for a photosensitive layer of these lithographic printing plate materials, there are known reaction product by a reaction of a methacrylate compound having hydroxyl group, a tertiary amino compound having hydroxyl group in each molecule, and a diisocyanate compound (see Patent Document 3).

However, these printing plate materials have still problems in that sensitivity is insufficient or long developing time is necessary.

Patent Document 1: JP-A No. 2000-98605,

Patent Document 2: JP-A No. 2001-264978,

Patent Document 3: Japan Patent Publication No. 2669849.

### DISCLOSURE OF THE INVENTION

### Problems to be Solved by the Invention

An object of the invention is to provide a photosensitive lithographic printing plate material adapted to a laser emitting light with an emission wavelength of from 350 to 450 nm, which provides high sensitivity and excellent development performance.

### Means for Solving the Problems

The above object has been attained by one of the following constitutions:

1. A photosensitive lithographic printing plate material comprising a support and provided thereon, a photosensitive layer containing (A) polymerization initiator, (B) polymerizable ethylenically double bonded compound, (C) sensitizing dye, and (D) polymeric binder,

wherein the photosensitive layer comprising a reaction product, as polymerizable ethylenic double bond having compound (B), by a reaction of (BM1) a compound having at least one polymerizable ethylenic double bond and one compound having one hydroxyl group, (BM2) a compound having in each molecule one secondary amino group and one hydroxyl group, and (BM3) a diisocyanate compound; and

wherein a molar ratio (R) of a number of moles of the (BM1) to a number of moles of the (BM2) (a number of moles of the (BM1)/a number of moles of the (BM2)) is in the range of 2.4 to 38.0.

2. The photosensitive lithographic printing plate material of item 1, wherein the molar ratio (R) is in the range of 3.0 to 18.0.

3. The photosensitive lithographic printing plate material of item 1 or 2, wherein (A) the polymerization initiator comprising a compound of hexaarylbiimidazole.

### EFFECTS OF THE INVENTION

An object of the invention is to provide a photosensitive lithographic printing plate material adapted to a laser emitting light with an emission wavelength of from 350 to 450 nm, which provides high sensitivity and excellent development performance.

### THE BEST EMBODIMENT FOR EMBODYING THE INVENTION

The present invention will be explained in detail below, however the present invention is not limited thereto.

The photosensitive lithographic printing plate material comprising a support and provided thereon, a light layer containing (A) polymerization initiator, (B) compound having a polymerizable ethylenically double bonded compound, (C) sensitizing dye, and (D) polymeric binder,

wherein the photosensitive layer comprising, as (B) compound having the polymerizable ethylenic double bond, a reaction product obtained by reaction of (BM1) compound, (BM2) compound and (BM3) compound, wherein (BM1) has in each molecule at least one polymerizable ethylenic double bond and one hydroxyl group, (BM2) has in each molecule one secondary amino group and one hydroxyl group and (BM3) is a diisocyanate compound; and

wherein a molar ratio (R) of a number of moles of (BM1) to a number of moles of (BM2)(a number of moles of the (BM1)/a number of moles of (BM2)) is in the range of 2.4 to 38.0.

In the invention, use of the polymerizable compound in the photosensitive layer especially provides a photosensitive lithographic printing plate material having high sensitivity and excellent development performance.

### ((B) Polymerizable Ethylenically Double Bonded Compound)

The photosensitive layer of the present invention comprises a reaction product, as polymerizable ethylenically double bonded compound (B) by a reaction of (BM1) compound having at least one polymerizable ethylenic double bond and one compound having one hydroxyl group, (BM2) compound having one secondary amino group and one hydroxyl group, and (BM3) diisocyanate compound.

In the invention, (BM1) is a compound having a polymerizable ethylenic double bond and hydroxyl group in the molecule, such as acrylate or methacrylate having hydroxyl group. Specific example of (BM1) include 2-hydroxyethyl methacrylate, 2-hydroxypropyl methacrylate, 2-hydroxyethyl acrylate, 2-hydroxypropyl acrylate, 4-hydroxybutyl acrylate, 2-hydroxy-3-methacryloyl oxypropyl methacrylate, and 2-hydroxy-3-acryloyl oxypropyl methacrylate.

(BM2) of the present invention is a compound having in each molecule one secondary amino group and one hydroxyl group. Examples of (BM2) include N-n-butyldiethanolamine, N-methylethanolamine, N-ethylethanolamine, 2-(2-hydroxyethyl)piperazine, N-isopropylethanolamine, and N-butyl-4-hydroxybutylamine.

(BM3) of the present invention is a compound having a two isocyanate groups. Examples of (BM3) include xylene diisocyanate, tetramethyl xylene diisocyanate, hexamethylene diisocyanate, isophorone diisocyanate, 1,3-diisocyanato benzene, 1,3-dicyanato-4-methylbenzene, and trimethylhexamethylene diisocyanate.

The reaction of the present invention can be carried out under a general condition of an urethane reaction that is reacted under the presence of a catalyst such as a tin complex in a solution which does not contain a functional groups such as an amino group, a hydroxyl group and a carboxyl group.

Namely, the reaction can be carried out by dissolving (BM1), (BM2) and (BM3) in the solvent; and heating under the coexistence of a polymerization exhibitor, for example hydroquinone monomethylether and a catalyst such as di-N-butyltin dilaurate.

The heating temperature is preferably in the range of 20° C. to 80° C., more preferably in the range of 30° C. to 60°.

The reacted product of the present invention can be obtained by reacting under reaction time between 30 minutes and 10 hours.

Further a method for forming the reacted product is preferably used in which (BM3) is added after a reaction of (BM1) and (BM2) is carried out in from 10 minutes to 1 hour at first and further the reaction is continued.

Specific examples of the reacted product are shown below:

TABLE 1

| Reaction | (BM1) | (BM2) | (BM3) | |
|---|---|---|---|---|
| Product | (Mol) | (Mol) | (Mol) | (R) |
| 1 | BM1-1 | BM2-1 | BM3-1 | 2.4 |
| | 1.1 | 0.49 | 1.0 | |
| 2 | BM1-2 | BM2-5 | BM3-7 | 3.6 |
| | 1.2 | 0.4 | 1.0 | |
| 3 | BM1-5 | BM2-4 | BM3-3 | 3.0 |
| | 1.2 | 0.4 | 1.0 | |
| 4 | BM1-3 | BM2-2 | BM3-4 | 3.0 |
| | 1.2 | 0.4 | 1.0 | |
| 5 | BM1-6 | BM2-6 | BM3-2 | 3.0 |
| | 1.2 | 0.4 | 1.0 | |
| 6 | BM1-4 | BM2-3 | BM3-6 | 6.0 |
| | 1.5 | 0.25 | 1.0 | |
| 7 | BM1-1 | BM2-5 | BM3-1 | 8.0 |
| | 1.6 | 0.2 | 1.0 | |
| 8 | BM1-1 | BM2-5 | BM3-1 | 11.3 |
| | 1.7 | 0.15 | 1.0 | |
| 9 | BM1-1 | BM2-5 | BM3-1 | 18.0 |
| | 1.8 | 0.1 | 1.0 | |
| 10 | BM1-1 | BM2-5 | BM3-1 | 38.0 |
| | 1.9 | 0.05 | 1.0 | |

(BM1)
BM1-1: 2-hydroxyethyl methacrylate
BM1-2: 2-hydroxypropyl methacrylate
BM1-3: 2-hydroxyethyl acrylate
BM1-4: 2-hydroxypropyl acrylate
BM1-5: 4-hydroxybutyl acrylate
BM1-6: 2-hydroxy-3-methacryloyl oxypropyl methacrylate
BM1-7: 2-hydroxy-3-acryloyl oxypropyl methacrylate
(BM2)
BM2-1: N-n-butyldiethanolamine
BM2-2: N-methylethanolamine
BM2-3: N-ethylethanolamine
BM2-4: 2-(2-hydroxyethyl)piperizine
BM2-5: N-isopropylethanolamine
BM2-6: N-butyl-4-hydroxybutylamine
(BM3)
BM3-1: xylene diisociyanate
BM3-2: tetramethyl xylene diisociyanate
BM3-3: hexamethylele diisociyanate
BM3-4: isophoron diisocyanate
BM3-5: 1,3-diisocyanato benzene
BM3-6: 1,3-dicyanato-4-methylbenzene
BM3-7: trimethylhexamethylene diisocyanate

Among them, the reacted products of reacting 2-hydroxyethyl methacrylate, 2-(2-hydroxyethyl piperazine and trimethylhexamethylene diisocyanate; and 2-hydroxyethyl methacrylate, 2-(2-hydroxyethyl)piperazine and hexamethylele diisocyanate are preferable.

Among them, the reacted product having the ratio (R) of or more is especially preferable. Further when molecular number of BM3 is 1.0, a value of mole of (BM1)+(BM2)×2 is preferably in the range of 1.8 to 2.2.

A content of the reaction product synthesized by above process to the photosensitive layer is preferably in the range of 3% to 90% by mass, especially preferable in the range of 5% to 60% by mass.

A conventional radically polymerizable compound, so called light polymerizable monomers and oligomers, can be used in combination in the invention.

The monomers are not specifically limited. Typical examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryl-oxyethyl acrylate, tetrahydrofurfuryloxyhexanorideacrylate, an ester of 1,3-dioxane-ε-caprolactone adduct with acrylic acid, or 1,3-dioxolane acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triadrylate, propionic acid dipentaerythritol triacrylate, propionic acid dipentaerythritol tetraacrylate or hydroxypivalylaldehyde modified dimethylolpropane triacrylate; a methacrylate, itaconate, crotonate or maleate alternative of the above polyfunctional acrylate.

A prepolymer can be used, and examples of the prepolymer include compounds as described later. The prepolymer with a photopolymerizable property, which is obtained by incorporating acrylic acid or methacrylic in an oligomer with an appropriate molecular weight, can be suitably employed. These prepolymers can be used singly, in combination or as their mixture with the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate r hydroxyethylphthalyl methacrylate.xylenediisocyanate, 1,2-polybutadieneglycol.tolylenedilsocyanate-2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

The photosensitive layer in the invention may contain a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

The ethylenic monomer used in the invention is preferably a phosphate compound having at least one (meth)acryloyl group. The phosphate compound is a compound having a (meth)acryloyl group in which at least one hydroxyl group of phosphoric acid is esterified, and the phosphate compound is not limited as long as it has a (meth)acryloyl group.

Besides the above compounds, compounds disclosed in JP-A Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV.EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

In addition to the above, acrylates or methacrylates disclosed in JP-A Nos. 2-105238 and 1-127404 can be used.

A content of the ethylenically double bonded compound (B) containing reaction product in photosensitive layer of the present invention is preferably from 5 to 70% by mass, and more preferably from 10 to 60% by mass based on the photosensitive layer.

((A) Polymerization Initiator)

The polymerization initiator in the invention is a compound which initiates polymerization of an ethylenically double bonded compound on light exposure. As a polymerization initiator, a titanocene compound, a monoalkyltriaryl borate compound, an iron-arene complex compound, a polyhalogenated compound, and a biimidazole compound are preferably used. Among them, the effect of the invention is excellent by using a biimidazole compound.

The biimidazole compound is a derivative of biimidazole, and examples thereof include those disclosed in for example, JP-A No. 2003-295426

In the invention, a hexaarylbisimidazole (HABI, a dimer of a triarylimidazole) compound is preferred as the biimidazole compound.

The synthetic method of the hexaarylbisimidazoles (HABI, dimmers of triarylimidazoles) is disclosed in DE 1470154, and use thereof in a photopolymerizable composition is disclosed in EP 24629, EQ 107792, U.S. Pat. No. 4,410,621, EP 215453 and DE 321312.

Preferred examples of the biimidazole compound include 2,4,5,2′,4′,5′-hexaphenylbisimidazole 2,2′-bis(2-chlorophenyl)-4,5,4′, 5′-tetraphenylbisimidazole, 2,2′-bis(2-bromophenyl)-4,5,4′,5′-tetraphenylbisimidazole, 2,2′-bis(2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,4′-tetrakis(3,4,5-trimethoxyphenyl)bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole, and 2,2′-bis(2,6-difluorophenyl)-4,5,4′,5′-tetraphenylbisimidazole.

As the titanocene compounds, there are those described in JP-A Nos. 63-41483 and 2-291, Preferred examples of titanocene compounds include bis(cyclopentadienyl)-Ti-di-chloride, bis(cyclopentadienyl)-Ti-bis-phenyl, bis(cyclopentadienyl)-Ti-bis-2,3,4,5,6-pentafluorophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 784, produced by Ciba Speciality Chemicals Co.), bis(cyclopentadienyl)-bis(2,4,6-trifluoro-3-(pyry-1-yl)phenyl)titanium, and bis(cyclopentadienyl)-bis(2,4,6-trifluoro-3-(2-5-dimethylpyry-1-yl)phenyl)titanium.

As the monoalkyltriaryl borate compounds, there are those described in Japanese Patent O.P.I. Publication Nos. 62-150242 and 62-143044. Preferred examples of the monoalkyl-triaryl borate compounds include tetra-n-butyl ammonium n-butyl-trinaphthalene-1-yl-borate, tetra-n-butyl ammonium n-butyl-triphenyl-borate, tetra-n-butyl ammonium n-butyl-tri-(4-tert-butylphenyl)-borate, tetra-n-butyl ammonium n-hexyl-tri-(3-chloro-4-methylphenyl)-borate, and tetra-n-butyl ammonium n-hexyl-tri-(3-fluorophenyl)-borate.

As the iron-arene complexes, there are those disclosed in JP-A No. 59-219307.

Preferred examples of the iron-arene complex include η-benzene-(η-cyclopentadienyl)iron hexafluorophosphate, η-cumene-(η-cyclopentadienyl)iron hexafluorophosphate, η-fluorene-(η-cyclopentadienyl)iron hexafluorophosphate, η-naphthalene-η-cyclopentadienyl)iron hexafluorophosphate, η-xylene-η-cyclopentadienyl)iron hexafluorophosphate, and η-benzene-η-cyclopentadienyl)iron tetrafluorophosphate.

As the polyhalogenated compound is preferably used a compound having a trihalomethyl group, a dihalomethyl group or a dihalomethylene group. In the invention, a polyhalogenated compound represented by the following Formula (B) or a compound having the oxadiazole ring the group described above as the substituent is preferably used.

A polyhalogenated compound represented by the following Formula (C) is especially preferably used.

R¹—CY₂—(C═O)—R² Formula (B)

wherein R¹ represents a hydrogen atom, a halogen atom, an alkyl group, an aryl group, an acyl group, an alkylsulfonyl group, an arylsulfonyl group, an iminosulfo group or a cyano group; R² represents a monovalent substituent, provided that R¹ and R² may combine with each other to form a ring; and Y represents a halogen atom.

CY₃—(C═O)—X—R³ Formula (C)

wherein 3 represents a monovalent substituent; X represents —O— or —NR⁴— in which R⁴ represents a hydrogen atom or an alkyl group, provided that when X represents —NR⁴—, R³ and R⁴ may combine with each other to form a ring; and Y represents a halogen atom.

Among these, a polyhalogenated compound having a polyhaloacetylamido group is preferably used.

An oxadiazole compound having in the oxadiazole ring a polyhalomethyl group as the substituent is preferably used. An oxadiazole compound disclosed in JP-A Nos. 5-34904 and 8-240909 also is preferably used.

Another photopolymerization initiator can be used in combination. Examples thereof include carbonyl compounds, organic sulfur compounds, peroxides, redox compounds, azo or diazo compounds, halides and photo-reducing dyes disclosed in J Kosar, “Light Sensitive Systems”, Paragraph 5, and further specific compounds disclosed in British Patent No. 1,459,563.

Typical examples of the photopolymerization initiator used in combination include the following compounds:

A benzoin derivative such as benzoin methyl ether, benzoin i-propyl ether, or α,α-dimethoxy-α-phenylacetophenone; a benzophenone derivative such as benzophenone, 2,4-dichlorobenzophenone, o-benzoyl methyl benzoate, or 4,4′-bis(dimethylamino) benzophenone; a thioxanthone derivative such as 2-chlorothioxanthone, 2-i-propylthioxanthone; an anthraquinone derivative such as 2-chloroanthraquinone or 2-methylanthraquinone; an acridone derivative such as N-methylacridone or N-butylacridone; α,α-diethoxyacetophenone; benzil; fluorenone; xanthone; an uranyl compound; a triazine derivative disclosed in Japanese Patent Publication Nos. 59-1281 and 61-9621 and JP-A No. 60-60104; an organic peroxide compound disclosed in JP-A Nos. 59-1504 and 61-243807; a diazonium compound in Japanese Patent Publication Nos. 43-23684, 44-6413, 47-1604 and U.S. Pat. No. 3,567,453; an organic azide compound disclosed in U.S. Pat. Nos. 2,848,328, 2,852,379 and 2,940,853; orthoquinondiazide compounds disclosed in Japanese Patent Publication Nos. 36-22062, 37-13109, 38-18015 and 45-9610; various onium compounds disclosed in Japanese Patent Publication No. 55-39162, JP-A No. 59-14023 and “Macromolecules”, Volume 10, p. 1307 (1977); azo compounds disclosed in JP-A No. 59-142205; metal arene complexes disclosed in JP-A No. 1-54440, European Patent Nos. 109,851 and 126,712, and “Journal of Imaging Science”, Volume 30, p. 174 (1986); (oxo) sulfonium organoboron complexes disclosed in Japanese Patent Application Nos. H4-56831 and 4-89535; transition metal complexes containing a transition metal such as ruthenium disclosed in “Coordination Chemistry Review”, Volume 84, p. 85-277 (1988) and JP-A No. 2-182701; 2,4,5-triarylimidazol dimmer disclosed in JP-A No. 3-209477; carbon tetrabromide; organic halide compounds disclosed in JP-A No. 59-107344.

The content of the polymerization initiator in the photosensitive layer (total content of the polymerization initiators) is preferably from 0.1 to 20% by mass, and more preferably from 0.5 to 15% by mass, based on the photosensitive layer.

### ((C) Sensitizing Dye)

The sensitizing dye according to this invention is a dye capable of sensitize the polymerization initiator, and preferably has a maximum absorption at wave length of 350-450 nm.

Sensitizing dyes include cyanines, merocyanines, porphyrins, spiro compounds, ferrocenes, fluorenes, fulgides, imidazoles, perylenes, phenazines, phenothiazines, acridines, azo compounds, diphenylmethanes, triphenylmethanes, triphenylamines, quinacridones, indigos, styryls, pyrylium compounds, pyrromethene compounds, pyrazolotriazole compounds, benzothiazole compounds, barbituric acid derivatives, thiobarbituric acid derivatives, ketoalcohol borate complex, cumarine derivatives, stilbene derivatives, phenyloxazole derivatives and acridone derivatives.

A coumarin derivative, a stilbene derivative, a phenyloxazole derivatives and an acridone derivatives among them are preferably employed in this invention.

The coumalin derivative represented by the following formula (D) is preferably employed.

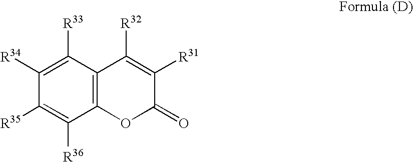

In the above formula R³¹ to R³⁶ is each a hydrogen atom or a substituent. Examples of a substituent include an alkyl group (e.g., methyl, ethyl, propyl, isopropyl, tert-butyl, pentyl, hexyl, octyl, dodecyl, tridecyl, tetradecyl, pentadecyl), a cycloalkyl group (e.g., cyclopentyl, cyclohexyl), an alkenyl group (e.g., vinyl, allyl), an alkynyl group (e.g., ethynyl, propargyl), an aryl group (e.g., phenyl, naphthyl), a heteroaryl group (e.g., furyl, thienyl, pyridyl, pyridazyl, pyrimidyl, pyrazyl, triazyl, imidazolyl, pyrazolyl, thiazolyl, benzimidazolyl, benzoxazolyl, quinazolyl, phthalazyl), a heterocyclic group (e.g., pyrrolidyl, imidazolidyl, morpholyl, oxazolidyl), an alkoxy group (e.g., methoxy, ethoxy, propyloxy, pentyloxy, hexyloxy, octyloxy, dodecyloxy), a cycloalkoxy group (e.g., cyclopentyloxy, cyclohexyloxy), an aryloxy group (e.g., phenoxy, naphthyloxy), an alkylthio group (e.g., methylthio, ethylthio, propylthio, pentylthio, hexylthio, octylthio, dodecylthio), a cycloalkylthio group (e.g., cyclopentylthio, cyclohexylthio), an arylthio group (e.g., phenylthio, naphthylthio), an alkoxycarbonyl group (e.g., methyloxycarbonyl, ethyloxycarbonyl, butyloxycarbonyl, octyloxycarbonyl, dodecyloxycarbonyl), an aryloxycarbonyl group (e.g., phenyloxycarbonyl, naphthyloxycarbonyl), a sulfamoyl group (e.g., aminosulfonyl, methylaminosulfonyl, dimethylaminosulfonyl, butylaminosulfonyl, hexylaminosulfonyl, cyclohexylaminosulfonyl, octylaminosulfonyl, dodecylaminosulfonyl, phenylaminosulfonyl, naphthylaminosulfonyl, 2-pyridylaminosulfonyl), an acyl group (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl), an acyloxy group (e.g., acetyloxy, ethylcarbonyloxy, butylcarbonyloxy, octylcarbonyloxy, dodecylcarbonyloxy, phenylcarbonyloxy), an amido group (e.g., methylcarbonylamino, ethylcarbonylamino, dimethylaminocarbonyl, propylcarbonylamino, pentylcarbonylamino, cyclohexylcarbonylamino, 2-ethylhexylcarbonylamino, octylcarbonylamino, dodecylcarbonylamino, phenylcarbonylamino, naphthylcarbonylamino), a carbamoyl group (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl), an ureido group (e.g., methylureido, ethylureido, pentylureido, cyclohexylureido, octylureido, dodecylureido, phenylureido, naphthylureido, 2-pyridylureido), a sulfinyl group (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, 2-pyridylsulfinyl), an alkylsulfonyl group (e.g., methylsulfonyl, ethylsulfonyl, butylsulfonyl, cyclohexylsulfonyl, 2-ethylhexylsulfonyl, dodecylsulfinyl), an arylsulfonyl group (e.g., phenylsulfonyl, naphthylsulfonyl, 2-pyridylsulfinyl), an amino group (e.g., amino, ethylamino, dimethylamino, butylamino, cyclopentylamino, 2-ethylhexylamino, dodecylamino, anilino, naphthylamino, 2-pyridylamino), a halogen atom (e.g., fluorine, chlorine, bromine, iodine), a cyano group, a nitro group, and a hydroxy group. These substituents may be further substituted by substituents described above. A plurality of these substituents may combine with each other to form a ring.

Of these is specifically preferred a coumalin containing, as R³⁵, an amino group, an alkylamino group, a dialkylamino group, an arylamino group, a diarylamino group or an alkylarylamino group. In that case, a coumalin in which an alkyl group substituted for an amino group combines with a substituent of R³⁴ or R³⁶ is also preferred.

More preferably, one of R³¹ and R³² or both of them are an alkyl group (e.g., methyl, ethyl, propyl, isopropyl, tert-butyl, pentyl, hexyl, octyl, dodecyl, tridecyl, tetradecyl, pentadecyl), a cycloalkyl group (e.g., cyclopentyl, cyclohexyl), an alkenyl group (e.g., vinyl, allyl), an aryl group (e.g., phenyl, naphthyl), a heteroaryl group (e.g., furyl, thienyl, pyridyl, pyridazyl, pyrimidyl, pyrazyl, triazyl, imidazolyl, pyrazolyl, thiazolyl, benzimidazolyl, benzoxazolyl, quinazolyl, phthalazyl), a heterocyclic group (e.g., pyrrolidyl, imidazolidyl, morpholyl, oxazolidyl), an alkoxycarbonyl group (e.g., methyloxycarbonyl, ethyloxycarbonyl, butyloxycarbonyl, octyloxycarbonyl, dodecyloxycarbonyl), an aryloxycarbonyl group (e.g., phenyloxycarbonyl, naphthyloxycarbonyl), an acyl group (e.g., acetyl, ethylcarbonyl, propylcarbonyl, pentylcarbonyl, cyclohexylcarbonyl, octylcarbonyl, 2-ethylhexylcarbonyl, dodecylcarbonyl, phenylcarbonyl, naphthylcarbonyl, pyridylcarbonyl), an acyloxy group (e.g., acetyloxy, ethylcarbonyloxy, butylcarbonyloxy, octylcarbonyloxy, dodecylcarbonyloxy, phenylcarbonyloxy), a carbamoyl group (e.g., aminocarbonyl, methylaminocarbonyl, dimethylaminocarbonyl, propylaminocarbonyl, pentylaminocarbonyl, cyclohexylaminocarbonyl, octylaminocarbonyl, 2-ethylhexylaminocarbonyl, dodecylaminocarbonyl, phenylaminocarbonyl, naphthylaminocarbonyl, 2-pyridylaminocarbonyl), a sulfinyl group (e.g., methylsulfinyl, ethylsulfinyl, butylsulfinyl, cyclohexylsulfinyl, 2-ethylhexylsulfinyl, dodecylsulfinyl, phenylsulfinyl, naphthylsulfinyl, 2-pyridylsulfinyl), an alkylsulfonyl group (e.g., methylsulfonyl, ethylsulfonyl, butylsulfonyl, cyclohexylsulfonyl, 2-ethylhexylsulfonyl, dodecylsulfinyl), an arylsulfonyl group (e.g., phenylsulfonyl, naphthylsulfonyl, 2-pyridylsulfonyl), a halogen atom (e.g., fluorine, chlorine, bromine), a cyano group, a nitro group or a halogenated alkyl group (e.g., trifluoromethyl, tribromomethyl, trichloromethyl).

Specific examples of a preferred coumalin dye are shown below but are not limited to these.

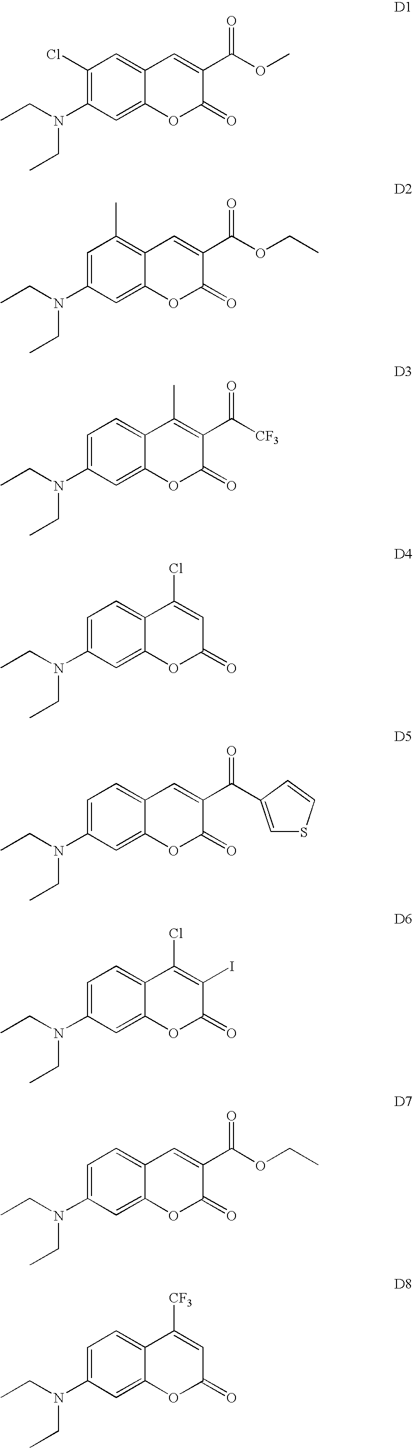

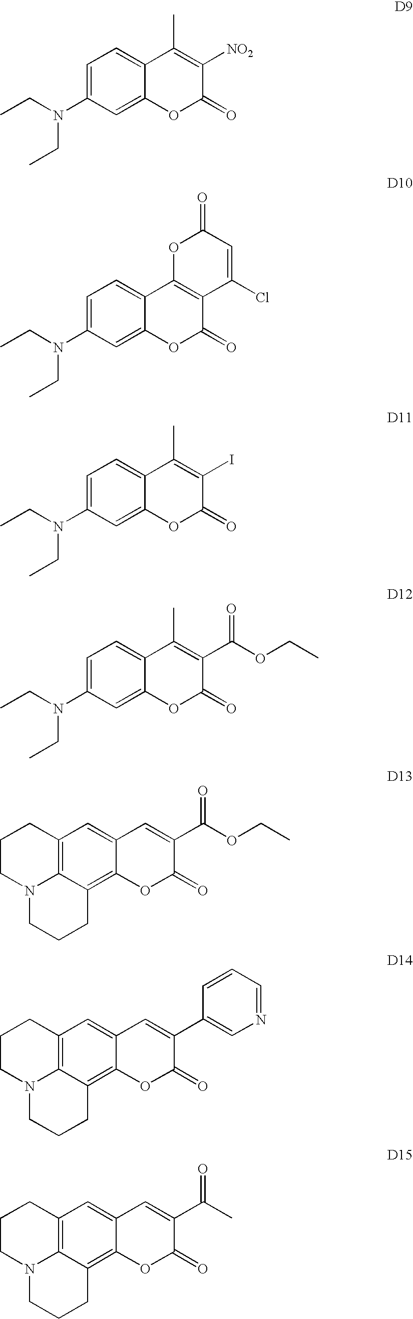

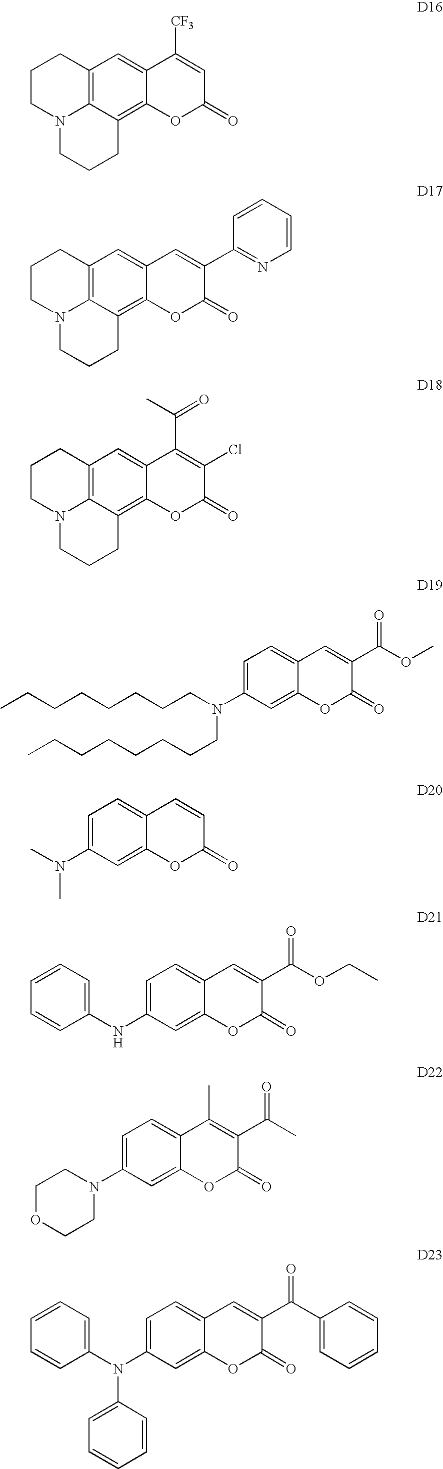

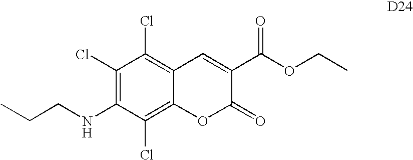

In addition to the foregoing examples, there are also preferably used coumalin derivatives of B-1 through B-22 described in JP-A H08-129258; coumalin derivatives of D-1 through D-32 described in JP-A 2003-21901; coumalin derivatives of 1 through 21 described in JP-A 2002-363206; coumalin derivatives of 1 through 40 described in JP-A 2002-363207; coumalin derivatives of 1 through 34 described in JP-A 2002-363208; and coumalin derivatives of 1 through 56 described in JP-A 2002-363209.

Compound represented by the following formulae (E) and (F) are preferably employed as the stilbene derivative.

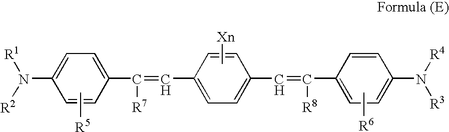

In the formula (E) R¹ through R⁴ represent, independently, a hydrogen atom, or an alkyl or aryl group which may have a substituent. R⁵ and R⁶ represent, independently, a hydrogen atom, a halogen atom, or an alkyl, aryl, alkoxy, or aryloxy group which may have a substituent. R⁷ and R⁸ represent, independently, a hydrogen atom, a halogen atom, a cyano group, or an alkyl group which may have a substituent. X is a halogen atom. n is an integer of 0-4.

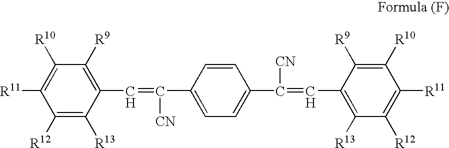

In the formula (F), R⁹ through R¹³ represent, independently, a hydrogen atom, a halogen atom, or an alkyl, alkoxy, aryl, aryloxy or alkyloxycarbonyl group which may have a substituent. R⁹ through R¹³ may form a ring by bonding each other.

Practical examples of compound represented by formula (E) and (F).

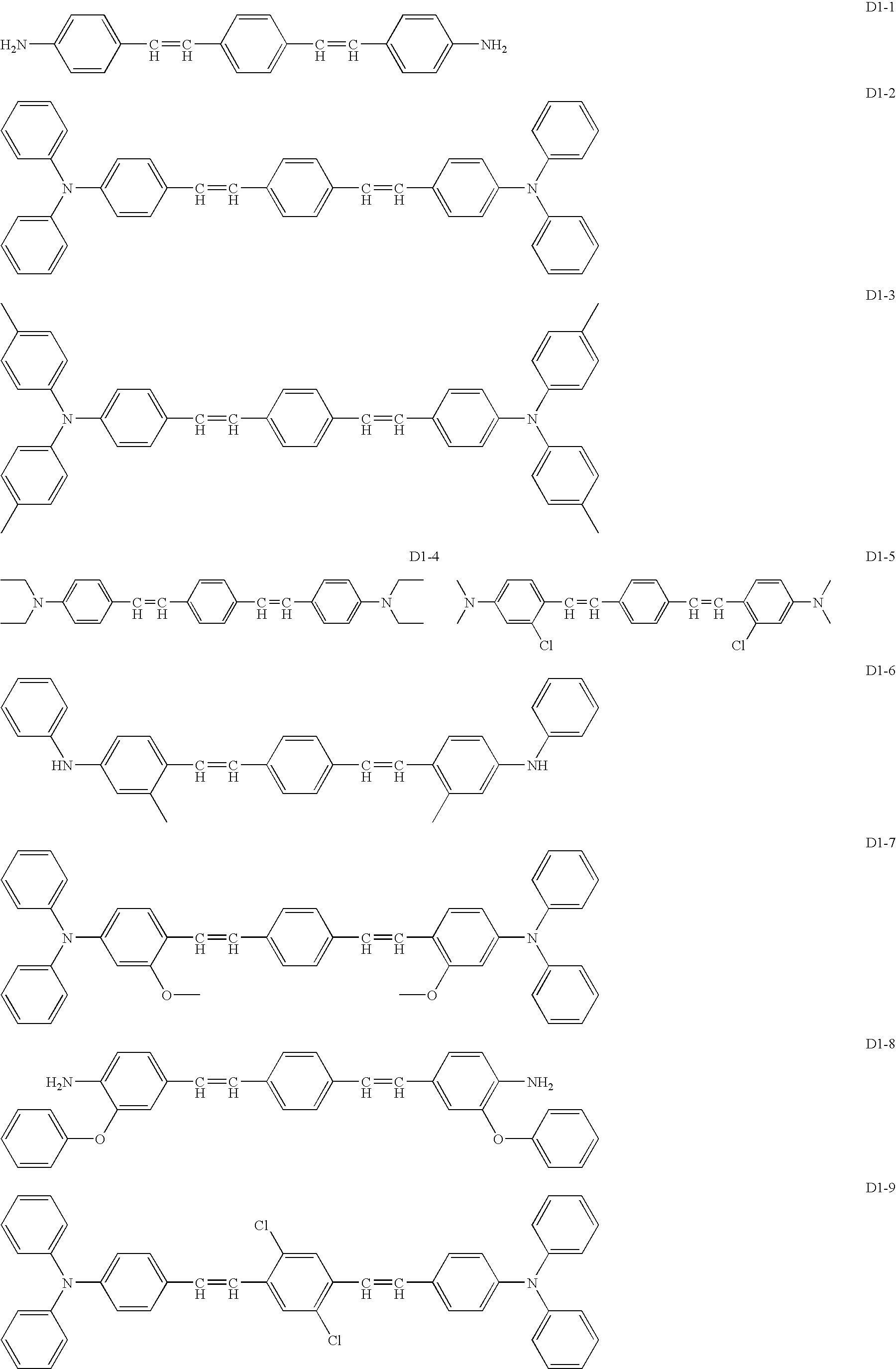

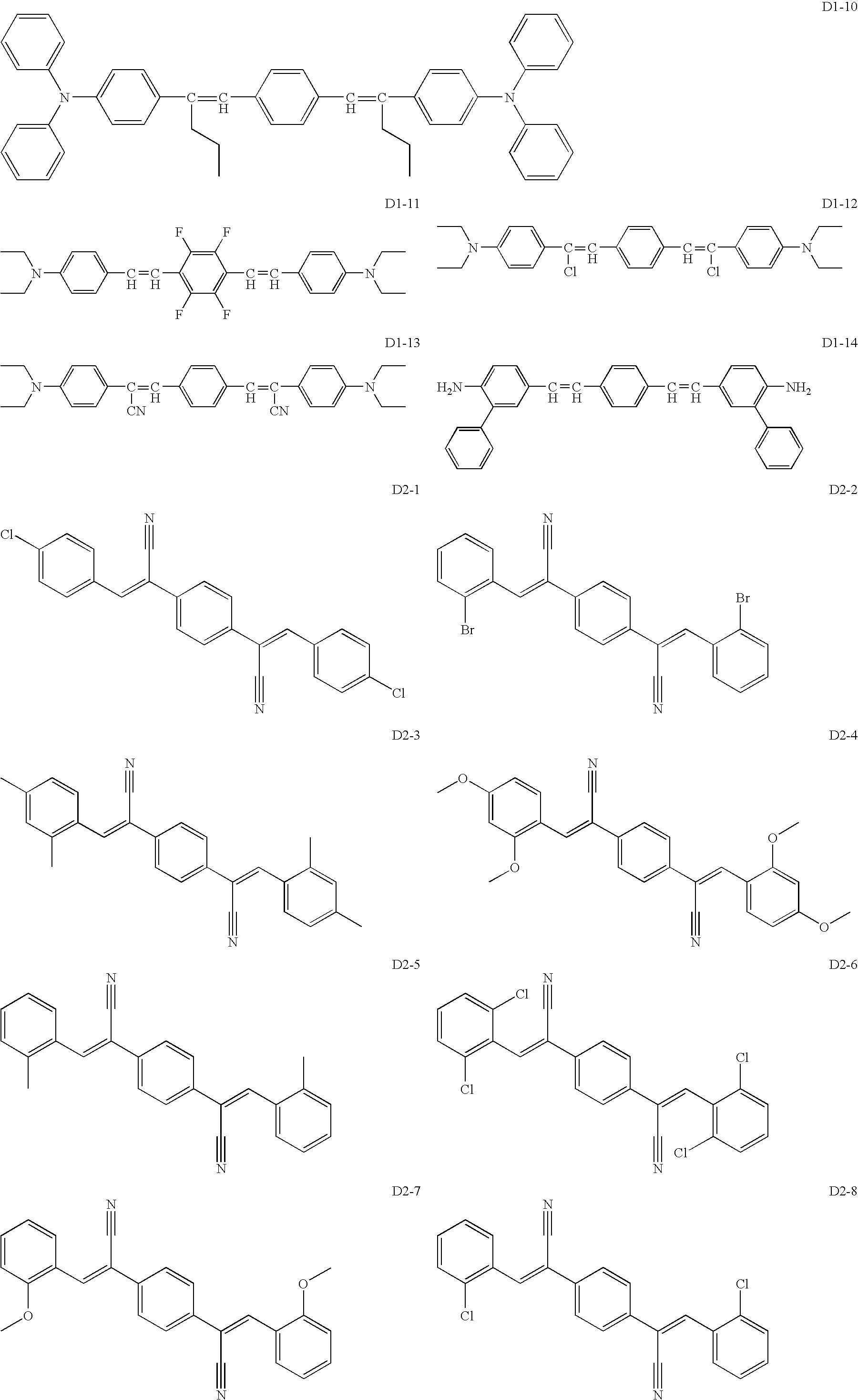

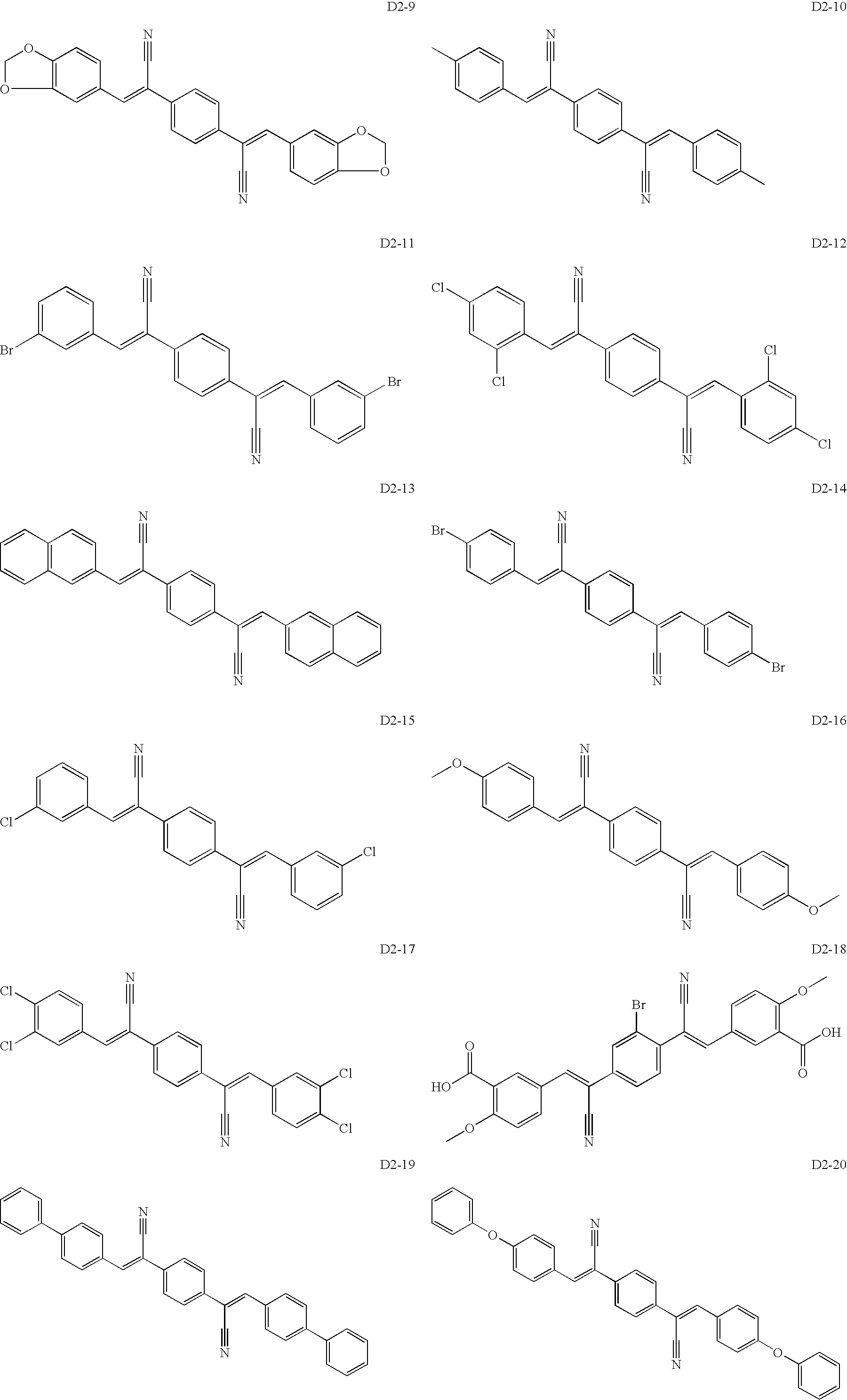

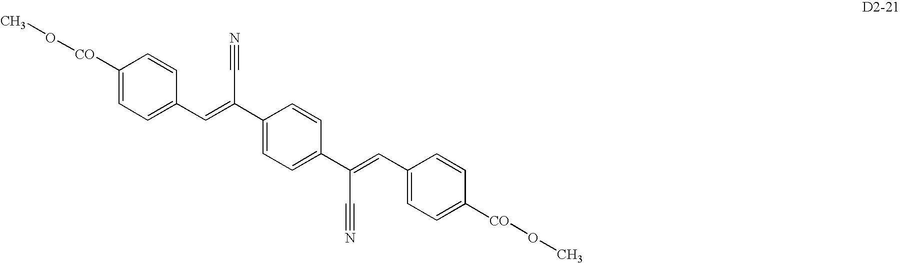

The following compound may be preferably used as a sensitizing dye.

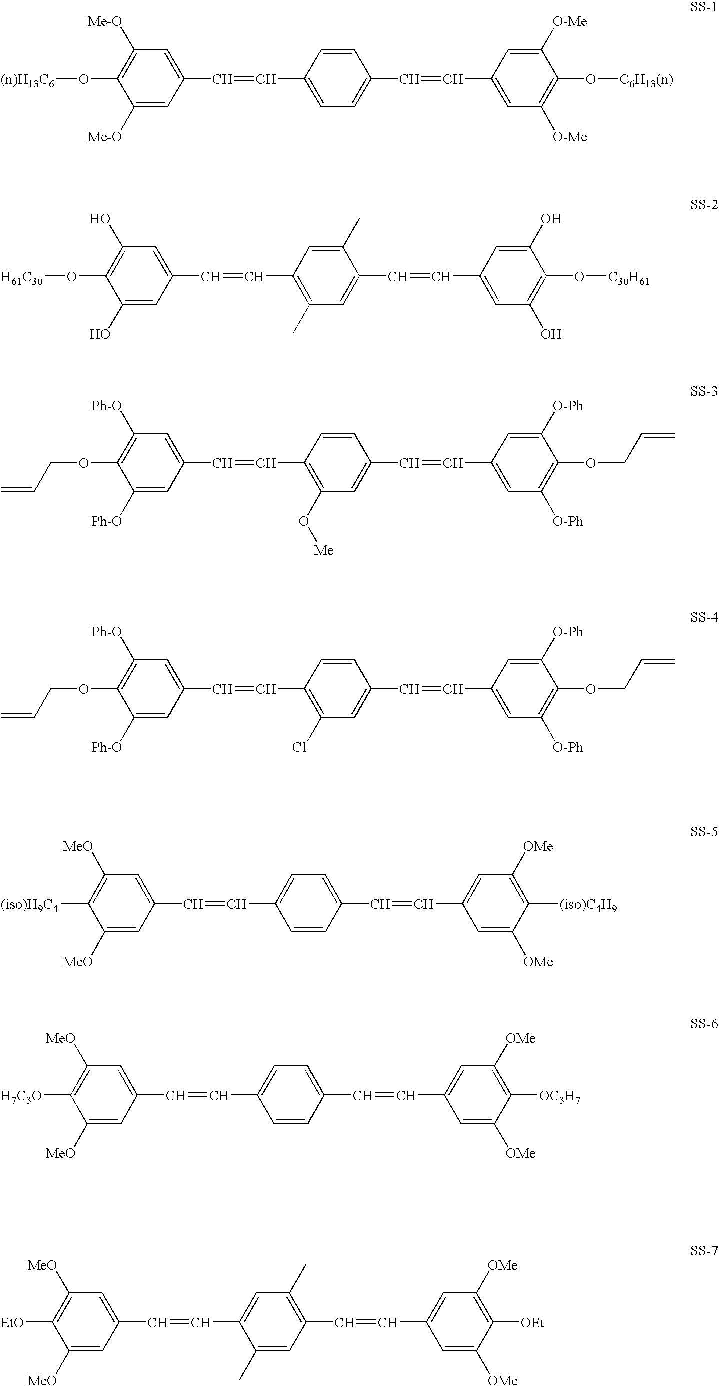

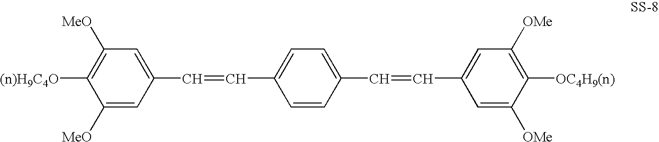

An amount of the sensitizing dye is preferably in the range of 0.3 to 10%, especially preferably in the range of 0.5 to 8% by mass in terms of the photosensitive layer.

Triphenyloxazoles such as 2,4,5-triphenyloxazole are preferably employed as the phenyloxazole derivatives.

Alkyl substituted acridones such as N-acridone are preferably employed as the acridone derivatives As the photosensitive layer in the invention can be preferably used 1,4-distyrylstilbene derivative, 2,4,5-triphenyloxazole derivatives, 7-dialkylamino coumarin derivative, N-alkyl acridone derivatives and styrylnaphthalene derivatives as the sensitizing dye

### ((D) Polymeric Binder)

As the polymeric binder in the invention can be used a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an mixture of two or more thereof.

The polymeric binder used in the invention is preferably a vinyl copolymer obtained by copolymerization of an acryl monomer, and more preferably a copolymer containing (a) a carboxyl group-containing monomer unit and (b) an alkyl methacrylate or alkyl acrylate unit as the copolymerization component.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymeric binder in the invention can further contain, as another monomer unit, a monomer unit derived from the monomer described in the following items (1) through (14):

1) A monomer having an aromatic hydroxy group, for example, o-, (p or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl) methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2-chloroethyl vinyl ether, propyl vinyl ether, butyl vinyl ether, octyl vinyl ether, or phenyl vinyl ether;

8) A vinyl ester, for example, vinyl acetate, vinyl chloroacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further another monomer may be copolymerized with the above monomer.

The polymeric binder is preferred which has, in the side chain of the molecule, both carboxyl group and polymerizable double bond. For example, an unsaturated bond-containing copolymer is preferred which is obtained by reacting a carboxyl group contained in the above vinyl copolymer molecule with for example, a compound having a (meth)acryloyl group and an epoxy group.

Examples of the compound having a unsaturated bond and an epoxy group in the molecule include glycidyl acrylate, glycidyl methacrylate and an epoxy group-containing unsaturated compound disclosed in JP-A No. 11-27196. Examples of the compound having both of an unsaturated bond and an isocyanate group in the molecule include vinyl isocyanate, (meth)acryl isocyanate, 2-(meth)acroyloxyethyl isocyanate, m- or p-isopropenyl-α,α′-dimethylbenzyl isocyanate, and (meth)acryl isocyanate, or 2-(meth)acroyloxyethyl isocyanate is preferred.

The content of the polymeric binder having in the side chain of the molecule both carboxyl group and polymerizable double bond is preferably from 50 to 100% by mass, and more preferably 100% by mass, based on the total content of the total polymeric binder.

The content of the polymeric binder in the photosensitive layer is preferably from 10 to 90% by mass, more preferably from 15 to 70% by mass, and still more preferably from 20 to 50% by mass, in view of sensitivity.

### (Mercapto Compound)

From the standpoint of sensitivity and fluctuation of sensitivity, the photosensitive layer in the invention preferably comprises a mercapto compound. The mercapto compounds are defined as compound having mercapto group. Specific example include: 2-mercaptobenzoxazole, 2-mercaptobenzimidazole, 2-mercaptobenzothiazole, 2-mercapto-4-methyl-5-acetylthiazole, 2-mercapto-4-methylthiazole, 1-methyl-2-mercaptoimidazole, 2-mercapto-4,5-dimethylthiazole, 2-mercapto-5-acetylthiazole, 1-methyl-2-mercaptobenzimidazole, 1-methyl-2-mercapto-4-methyl-5-acetylimidazole, 2-mercaptooxazole, 2-mercaptobenzooxazole, and 2-mercapto-2-imidazoline.

A content of the mercapto compound is preferably in the range of 0.01 to 50% by mass in terms of the photosensitive layer. (Various additives)

The photosensitive layer in the invention is preferably added with a polymerization inhibitor other than composition described above, in order to prevent undesired polymerization of the ethylenically double bonded monomer during the manufacture or after storage of photosensitive lithographic printing plate material.

Examples of the polymerization inhibitor include hydroquinone, p-methoxyphenol, di-t-butyl-p-cresol, pyrrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerous salt, and 2-t-butyl-6-(3-t-butyl-6-hydroxy-5-methylbenzyl)-4-methylphenyl acrylate.

The polymerization inhibitor content is preferably 0.01 to 5% by mass based on the total solid content of the photosensitive layer. Further, in order to prevent undesired polymerization induced by oxygen, behenic acid or a higher fatty acid derivative such as behenic amide may be added to the layer as appropriate. After the photosensitive layer is coated layer, the coated layer may be dried so that the higher fatty acid derivative is localized at the vicinity of the surface of the photosensitive layer. The content of the higher fatty acid derivative is preferably 0.5 to 10% by mass, based on the total solid content of the photosensitive layer.

A colorant can be also used. As the colorant can be used known materials including commercially available materials. Examples of the colorant include those described in revised edition “Ganryo Binran”, edited by Nippon Ganryo Gijutu Kyoukai (published by Seibunndou Sinkosha), or “Color Index Binran”. Pigment is preferred.

Kinds of the pigment include black pigment, yellow pigment/red pigment, brown pigment, violet pigment, blue pigment, green pigment, fluorescent pigment, and metal powder pigment. Examples of the pigment include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment).

Among these pigment, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment content is preferably 0.1 to 10% by mass, and more preferably 0.2 to 5% by weight, based on the total solid content of the above composition.

A purple pigment or a blue pigment is preferably utilized in view of absorption of light with the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone SC. Among them, more preferable are Phthalocyanine Blue and Dioxane Violet.

The photosensitive layer can contain surfactants as a coating improving agent as long as the performance of the invention is not jeopardized. Among these surfactants, a fluorine-contained surfactant is preferred.

Further, in order to improve physical properties of the cured photosensitive layer, the layer can contain an inorganic filler or a plasticizer such as dioctyl phthalate, dimethyl phthalate or tricresyl phosphate. The content of such a material is preferably not more than 10% by mass, based on the total solid content.

The solvents used in the preparation of the coating liquid for the photosensitive layer in the invention include an alcohol and a polyhydric alcohol such as sec-butanol, isobutanol, n-hexanol, or benzyl alcohol, diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

In the above, explanation of a photosensitive layer coating liquid was made. The photosensitive layer in the invention is formed on a support by coating on the support the photosensitive layer coating liquid.

The coating amount of the photosensitive layer is preferably from 0.1 to 10 g/m², and more preferably from 0.5 to 5 g/m².

(Protective Layer (Oxygen Shielding Layer))

In the invention, a protective layer is provided on the photosensitive layer as appropriate.

It is preferred that the protective layer (oxygen shielding layer) is highly soluble in the developer as described later (generally an alkaline solution). Polyvinyl alcohol or polyvinyl pyrrolidone is preferably used in the protective layer. Polyvinyl alcohol has the effect of preventing oxygen from transmitting and polyvinyl pyrrolidone has the effect of increasing adhesion between the oxygen shielding layer and the adjacent photosensitive layer.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide

In the lithographic printing plate material in the invention, adhesive strength between the protective layer and the photosensitive layer is preferably not less than 35 mN/mm, more preferably not less than 50 mN/mm, and still more preferably not less than 75 mN/mm. Preferred composition of the protective layer is disclosed in Japanese Patent Application No. 8-161645.

The adhesive strength can be determined according to the following method. The adhesive tape with a sufficient adhesive force is applied on the protective layer, and then peeled together with the protective layer under the applied tape in the normal direction relative to the protective layer surface. Force necessary to peel the tape together with the protective layer is defined as adhesive strength.

The protective layer may further contain a surfactant or a matting agent. The protective layer is formed, coating on the light polymerizable photosensitive layer a coating solution in which the above protective layer composition is dissolved in an appropriate coating solvent, and drying. The main solvent of the coating solution is preferably water or an alcohol solvent such as methanol, ethanol, or iso-propanol.

When the protective layer is provided, the thickness of the protective layer is preferably 0.1 to 5.0 μm, and more preferably 0.5 to 3.0 μm.

(Support)

The support used in the invention is a plate or a sheet capable of carrying the photosensitive layer and preferably has a hydrophilic surface on the side on which the photosensitive layer is to be provided.

As the supports used in the invention, a plate of a metal such as aluminum, stainless steel, chromium or nickel, or a plastic film such as a polyester film, a polyethylene film or a polypropylene film, which is laminated or deposited with the above-described metal can be used.

Further, a polyester film, a polyvinyl chloride film or a nylon film whose surface is subjected to hydrophilization treatment can be used. Among the above, the aluminum plate is preferably used.

When the aluminum plate is used, it may be a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. In the aluminum plate for the support, the surface is roughened for water retention.

It is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable.

Though there is no restriction for the electrolytic surface roughening method, a method, in which the support is electrolytically surface roughened in an acidic electrolytic solution, is preferred.

After the support has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used.

The dissolution amount of aluminum in the support surface is preferably 0.5 to 5 g/m² After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the support.

The support which has been subjected to anodizing treatment is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the support is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in JP-A No. 5-304358, which has a functional group capable of causing addition reaction by radicals as a covalent bond, is suitably used.

(Coating)

In the invention, the above-described photosensitive layer coating liquid is coated on the support according to a coating conventional method, and dried to obtain a photosensitive lithographic printing plate material.

Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method

A drying temperature of the coated photosensitive layer is preferably from 60 to 160° C., more preferably from 80 to 140° C., and still more preferably from 90 to 120° C.

(Imagewise Exposure)

As a light source for recording an image on the photosensitive lithographic printing plate material of the invention, a laser with an emission wavelength of from 370 to 440 nm is preferably used.

Examples of light sources for imagewise exposure of the photosensitive lithographic printing plate material include a He—Cd laser (441 nm), a combination of Cr:LiSAF and SHG crystals (430 nm) as a solid laser, and KnbO3, ring resonator (430 nm), AlGaInN (350-350 nm) or AlGaInN semiconductor laser (InGaN type semiconductor laser available on the market, 400-410 nm) as a semiconductor type laser.

When a laser is used for exposure, which can be condensed in the beam form, scanning exposure according to an image can be carried out, and direct writing is possible without using any mask material.

When the laser is employed for imagewise exposure, a highly dissolved image can be obtained, since it is easy to condense its exposure spot in minute size.

As a laser scanning method by means of a laser beam, there are a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fθ lens, and sub-scanning is carried out by moving a recording medium. The method of scanning on an outer surface of a cylinder and the method of scanning on an inner surface of a cylinder are suitable for high density image recording, since it is easier to increase accuracy of an optical system.

In the invention, imagewise exposure is carried out at a plate surface energy (an exposure energy at the surface of the lithographic printing plate material) of from 10 to 500 mJ/cm², and more preferably from 10 to 300 mJ/cm². This exposure energy can be measured, employing a laser power meter PDGDO-3W produced by Ophir Optronics Inc.

(Developer)

In the manufacturing method of the invention of a lithographic printing plate, the imagewise exposed photosensitive layer, which has been cured at exposed portions, is developed with an alkali developer, whereby the photosensitive layer at unexposed portions are removed to form an image.

As the alkali developer, a conventional alkali aqueous solution is used. For example, there is an alkali developer containing an inorganic alkali agent such as sodium silicate, potassium silicate, ammonium silicate; sodium secondary phosphate, potassium secondary phosphate, ammonium secondary phosphate; sodium bicarbonate, potassium bicarbonate, ammonium bicarbonate; sodium carbonate, potassium carbonate, ammonium carbonate; sodium hydrogen carbonate, potassium hydrogen carbonate, ammonium hydrogen carbonate; sodium borate, potassium borate, lithium borate; sodium hydroxide, potassium hydroxide, ammonium hydroxide, and lithium hydroxide.

The alkali developer can contain organic alkali agents such as monomethylamine, dimethylamine, trimethylamine, monoethylamine, diethylamine, triethylamine, mono-i-isopropylamine, di-i-isopropylamine, tri-i-isopropylamine, butylamine, monoethanolamine, diethanolamine, triethanolamine, mono-i-isopropanolamine, di-i-isopropanolamine, ethyleneimine, ethylenediamine, and pyridine.

These alkali agents can be used singly or as a mixture of two or more thereof. The alkali developer can contain an anionic surfactant, an amphoteric surfactant, or an organic solvent such as alcohol.

The alkali developer can be prepared from a developing composition in the form of tablets or granules or a developer concentrate.

The developer concentrate may be prepared by forming a developer solution, followed by evaporation to dryness and is preferably prepared in such a manner that plural components are mixed with a small amount of water or without adding any water. The developer concentrate can also be prepared in the form of granules or tablets, as described in JP-A Nos. 51-61837, 2-109042, 2-109043, 3-39735, 5-142786, 6-266062 and 7-13341. The developer concentrate may be divided into plural parts differing in material species or compounding ratio.

The developer or developer replenisher in the invention can further contain an antiseptic agent, a coloring agent, a viscosity increasing agent, an antifoaming agent, or a water softener.

(Automatic Developing Machine)

It is advantageous that an automatic developing machine is used in order to develop a photosensitive lithographic printing plate material. It is preferred that the automatic developing machine is equipped with a means for automatically introducing a developer replenisher in a necessary amount into a developing bath, a means for discharging any excessive developer and a means for automatically introducing water in necessary amounts to the developing bath. It is preferred that the automatic developing machine comprises a means for detecting a lithographic printing plate material to be transported, a means for calculating the area to be processed of the lithographic printing plate material based on the detection, or a means for controlling a replenishing amount of a developer replenisher, a replenishing amount of water to be replenished or replenishing timing based on the detection and calculation. It is also preferred that the automatic developing machine comprises a means for controlling a temperature of a developer, a means for detecting a pH and/or electric conductivity of a developer, or a means for controlling a replenishing amount of the developer replenisher, a replenishing amount of water to be replenished and/or the replenishing timing based on the detected pH and/or electric conductivity. It is also preferred that the automatic developing machine have a function of diluting a developer concentrate with water and a function of stirring the diluted concentrate Where developing is followed by washing, water used for washing can be reused as a dilution water for diluting the developer concentrate.

The automatic developing machine used in the invention may be provided with a pre-processing section to allow the plate to be immersed in a preprocessing solution prior to development. The pre-processing section is provided preferably with a mechanism of spraying a pre-processing solution onto the plate surface, preferably with a mechanism of controlling the pre-processing solution at a temperature within the range of 25 to 55° C., and preferably with a mechanism of rubbing the plate surface with a roller-type brush. Common water and the like are employed as the pre-processing solution.

(Post-Processing)

The developed printing plate material is preferably subjected to post-processing. The post-processing step comprises post-processing the developed precursor with a post-processing solution such as washing water, a rinsing solution containing a surfactant, a finisher or a protective gumming solution containing gum arabic or starch derivatives as a main component. The post-processing step is carried out employing an appropriate combination of the post-processing solution described above. For example, a method is preferred in which a developed lithographic printing plate precursor is post-washed with washing water, and then processed with a rinsing solution containing a surfactant, or a developed lithographic printing plate precursor is post-washed with washing water, and then processed with a finisher, since it reduces fatigue of the rinsing solution or the finisher. It is preferred that a multi-step countercurrent processing is carried out employing a rinsing solution or a finisher.

The post-processing is carried out employing an automatic developing machine having a development section and a post-processing section. In the post-processing step, the developed printing plate is sprayed with the post-processing solution from a spray nozzle or is immersed into the post-processing solution in a post-processing tank. A method is known in which supplies a small amount of water onto the developed printing plate precursor to wash the precursor, and reuses the water used for washing as dilution water for developer concentrate. In the automatic developing machine, a method is applied in which each processing solution is replenished with the respective processing replenisher according to the area of the printing plate precursor to have been processed or the operating time of the machine. A method (use-and-discard method) can be applied in which the developed printing plate material is processed with fresh processing solution and discarded. The thus obtained lithographic printing plate is mounted on a printing press, and printing is carried out.

### EXAMPLES

Next, the present invention will be explained in the following examples, but the present invention is not limited thereto. In the examples, “parts” represents “parts by mass”, unless otherwise specified.

[Synthesis Example of Compound (1) Having Polymerizable Ethylenic Double Bond]

Into a 2-liter four neck separable flask equipped with a stirrer, a temperature regulator, a thermometer and a condenser, were charged 431 g of propyleneglycol methyleter acetate, 210 g (1.0 mol) of trimethylhexamethylenediisocyanate, 182 g (1.4 mol) of 2-hydroxyethylmethacrylate and 0.2 g of hydroqunonemonomethylether. Then 0.3 g of dibutyl tin dilaurate was charged therein at 40-50° C. and reaction was allowed to proceed for 30 minutes. Further 38.8 g (0.3 mol) of 2-(2-hydroxyethyl)pyperrizine was charged therein and reaction was allowed to proceed for 3 hours. 50% propyleneglycol methyl ether acetate solution of a compound (1) having polymerizable ethylenic double band was obtained.

In this synthesis example, mol ratio (R) of (EMI) 2-hydroxyethylmethacrylate/(BM2) 2-(2-hydroxyethyl)pyperrizine was 4.7.

[Synthesis Example of Compound (2) to (10) Having Polymerizable Ethylenic Double Bond]

Compound (2) to (10) having polymerizable double bond were synthesized as the same manner above, except for changing a ratio of BM1, BM2 and BM3 as shown in Table 2 and 3.

TABLE 2

| | | | (BM3) | |
|---|---|---|---|---|
| | | (BM2) | 2,2,4- | |
| | (BM1) | 2-(2- | trimethyl- | |
| | 2-hydroxyethyl | hydroxyethyl) | hexamethylene- | Molar |
| Reaction | metacrylate | pyperydine | diisocyanate | Ratio |
| Product | (Mol) | (Mol) | (Mol) | (R) |
| (2) | 1.1 | 0.45 | 1.0 | 2.4 |
| (3) | 1.2 | 0.4 | 1.0 | 3.0 |
| (4) | 1.3 | 0.35 | 1.0 | 3.7 |
| (5) | 1.5 | 0.25 | 1.0 | 6.0 |
| (6) | 1.6 | 0.2 | 1.0 | 8.0 |
| (7) | 1.7 | 0.15 | 1.0 | 11.3 |
| (8) | 1.8 | 0.1 | 1.0 | 18.0 |
| (9) | 1.9 | 0.05 | 1.0 | 38.0 |

TABLE 3

| | | (BM2) | | |
|---|---|---|---|---|
| | (BM1) | 2-(2- | (BM3) | |
| | 2-hydroxyethyl | hydroxyethyl) | hexamethylene | Molar |
| Reaction | metacrylate | pyperydine | diisocyanate | Ratio |
| Product | (Mol) | (Mol) | (Mol) | (R) |
| (10) | 1.2 | 0.4 | 1.0 | 3.0 |

(Preparation of Support)

A 0.3 mm thick aluminum plate (material 1050, quality H16) was degreased at 60° C. for one minute in a 5% sodium hydroxide solution, washed with water, immersed at 25° C. for one minute in 10%, hydrochloric acid solution to neutralize, and then washed with water. The resulting aluminum plate was electrolytically surface roughened using an alternating current at 25° C. for 60 seconds at a current density of 100 A/dm² in a 0.3% nitric acid solution, and desmutted at 60° C. for 10 seconds in a 5% sodium hydroxide solution.

The desmutted aluminum plate was anodized at 25° C. for 1 minute at a current density of 10 A/dm² and at a voltage of 15 V in a 15% sulfuric acid solution, and further subjected to hydrophilization treatment at 75° C. in a 1% polyvinyl phosphonic acid solution. Thus, support was obtained.

The center line average surface roughness (Ra) of the support was 0.65 μm.

### (Preparation of Lithographic Printing Plate Material Sample)

The following photosensitive layer coating solution 1 was coated on the above support through a wire bar, and dried at 95° C. for 1.5 minutes with a coating amount of 1.5 g/m at dry state. Subsequently, the oxygen shielding layer coating solution 1 was coated on the resulting photosensitive layer using a wire bar, and dried at 75° C. for 1.5 minutes to give an oxygen shielding layer with a coating amount of 1.5 g/m² at dry state. Thus, inventive lithographic printing plate material samples 1 through 15 were prepared.

(Photosensitive Layer Coating Solution 1)

| | | |
|---|---|---|
| 50% propyleneglycol methylether acetate solution of | 84.0 | parts |
| compound having polymerizable ethylenically double | | |
| bond (shown in Table 4) | | |
| Triethylneglycol dimethacrylate | 6.0 | parts |
| Copolymer of methacrylic acid and methyl methacrylate | 35.0 | parts |
| (25:75 by mass) with a molecular weight of 36000 | | |
| Sensitizing dye (shown in Table 4) | 4.0 | parts |
| 2,2′-bis(2-chlorophenyl)-4,5,4′,5′-tetraphenyl | 3.0 | parts |
| biimidazole | | |
| 2-mercaptobenzothiazole | 0.3 | parts |
| N-phenyl glycinebenzylester | 4.0 | parts |
| Phthalocyanine pigment (MHI 454 produced by Mikuni | 3.5 | parts |
| Sikisosha) | | |
| 2-t-Butyl-6-(3-t-butyl-2-hydroxy-5-methylbenzyl)-4- | 0.2 | parts |
| methylphenylacrylate (Sumirizer GS: produced by | | |
| Sumitomo 3M Co., Ltd.) | | |
| 2,4,6-tris(dimethylaminomethyl)phenol | 1.0 | part |
| Bis(2,2,6,6-tetramethyl-4-pyperidyl)sebacate | 0.1 | parts |
| Fluorine-contained surfactant(F-178K: produced by | 0.5 | parts |
| Dainippon Ink Co., Ltd.) | | |
| Siloxane surfactant (BYK337: produced by BYK | 0.9 | parts |
| CHEMIE Co., Ltd.) | | |
| Methylethylketone | 80 | parts |
| Propylene glycol methyl ether | 820 | parts |

(Oxygen Shielding Layer Coating Solution 1)

| | | |
|---|---|---|
| Polyvinyl alcohol (Celvol 103: produced by Celanese | 85.0 | parts |
| Corporation) | | |
| Vinyl pyrrolidone-vinyl acetate copolymer (Luvitek | 15.0 | parts |
| VA64W, produced by BASF Inc.) | | |
| Surfinol 465 (produced by Air Products Inc.) | 0.2 | part |
| Water | 900 | parts |

(Preparation of Lithographic Printing Plate)

Each of the lithographic printing plate material samples obtained above was imagewise exposed at a resolving degree of 2400 dpi, employing a plate setter News CTP (produced by ECRM Co., Ltd.) equipped with a 405 nm light source with an output power of 60 mW. Herein, dpi represents the dot numbers per 2.54 cm.

The image pattern used for the exposure comprised a 100% solid image, an uppercase alphabet, and a lowercase alphabet of reverse text, the alphabets having a font of Times New Roman and a point size of 3 to 10.

Subsequently, the exposed sample was subjected to development treatment employing a CTP automatic developing machine (Raptor Polymer produced by Glunz & Jensen Inc.) to obtain a lithographic printing plate. Herein, the developing machine comprised a preheating section set at 105° C., a pre-washing section for removing the oxygen shielding layer before development, a development section set at 30° C. and charged with developer having the following developer composition, a washing section for removing the developer remaining on the developed sample after development, and a gumming section charged with a gumming solution (a solution obtained by diluting GW-3, produced by Mitsubishi Chemical Co., Ltd., with water by a factor of 2) for protecting the surface of the developed sample. Thus, lithographic printing plate sample was obtained.

(Developer Composition: Aqueous solution
containing the following components)

| | |
|---|---|
| Potassium silicate A | 8.0 parts |
| Newcol B-13SN (produced by Nippon | 3.0 parts |
| Nyukazai Co., Ltd.) | |
| Water | 89.0 parts |
| Potassium hydroxide | amount giving pH 12.3 |

### (Evaluation of Photosensitive Lithographic Printing Plate Material Samples)

The photosensitive lithographic printing plate material samples were evaluated based on the following reference.

<<Sensitivity>>

The minimum exposure energy (μJ/cm²), at which no thickness reduction of the solid image layer of the resulting printing plate obtained was observed, was defined as recording energy and evaluated as a measure of sensitivity. The less the recording energy is, the higher the sensitivity.

<<Developability>>

The developer was put into a beaker and stirred by a magnetic stirrer. A photosensitive lithographic printing plate material which was removed the oxygen shielding layer by washing was immersed and time until an elution of the photosensitive layer started was observed as the index of developability. Shorter time for the elution start to the developer exhibits good developability.

Results are shown in Table 4.

TABLE 4

| | Reaction | Sensidized | | |
|---|---|---|---|---|
| | Product | Dye | Sensitivity | Developability |
| Example 1 | (1) | D-1 | 15 μJ/cm² | 7 sec |
| Example 2 | (2) | D-1 | 25 μJ/cm² | 13 sec |
| Example 3 | (3) | D-1 | 20 μJ/cm² | 8 sec |
| Example 4 | (5) | D-1 | 15 μJ/cm² | 7 sec |
| Example 5 | (8) | D-1 | 20 μJ/cm² | 7 sec |
| Example 6 | (9) | D-1 | 25 μJ/cm² | 12 sec |
| Example 7 | (10) | D-2 | 15 μJ/cm² | 10 sec |
| Example 8 | (10) | D-3 | 15 μJ/cm² | 10 sec |
| Example 9 | (1) | D-4 | 15 μJ/cm² | 8 sec |
| Example 10 | (1) | D-5 | 15 μJ/cm² | 7 sec |
| Comp. 1 | RM-1 | D-2 | 40 μJ/cm² | 20 sec |
| Comp. 2 | RM-2 | D-1 | 80 μJ/cm² | 25 sec |
| Comp. 3 | RM-3 | D-1 | 35 μJ/cm² | 20 sec |

D-1: N-butylacrydone

D-2: 1,4-bis(4-i-butoxy-3,5-dimethoxystyryl)benzene

D-3-2-phenyl-4-(2-chlorophenyl)-5-(4-diethylaminophenyl)-oxazole

D-4: 3-phenyl-7-diethylinoqumarine

D-5: 1-(3,4,5-trimethoxystyryl)naphthalene

RM-1: Compound having polymerizable ethylenic double bond synthesized as the same manner as compound (10) having polymerizable ethylenic double bond except for changing the ratio of BM1:BM2:BM3 to 1:0.5:1. Ratio (R) is 2.0.

RM-2: Compound having polymerizable ethylenic double bond synthesized as the same manner as compound (1) having polymerizable ethylenic double bond except for eliminating BM2 and changing the ratio of BM1:BM3 to 2:1.

RM-3: Compound having polymerizable ethylenic double bond synthesized as the same manner as compound (9) having polymerizable ethylenic double bond except for changing the ratio of BM1:BM2:BM3 to 2.0:0.4:1. Ratio (R) is 50.

Photosensitive lithographic printing plate material samples 13 and 14 were prepared in the same manner as in the photosensitive lithographic printing plate material 1, except that 2-2′-bis(2-chlorophenyl)-4,5,4′,5′-tetraphenylbiimidazole in the photosensitive lithographic printing plate material 1 was replaced with 2,2′-bis(2,4-dichlorophenyl)-4,5,4′,5′-tetraphenylbiimidazole, 2,2′-bis(2-chlorophenyl)-4,5,4′,5′-tetrakis(3-methoxyphenyl)biimidazole. The resulting photosensitive lithographic printing plate material samples were evaluated in the same manner above, and the similar results were obtained as that of the photosensitive lithographic printing plate material 1.

From the above results, the photosensitive lithographic printing plate material of the present invention exhibit high sensitivity and excellent developability.

1. A photosensitive lithographic printing plate material comprising a support and provided thereon, a photosensitive layer containing (A) polymerization initiator, (B) compound having a polymerizable ethylenic double bond, (C) sensitizing dye, and (D) polymeric binder,
wherein the photosensitive layer comprising, as (B) compound having the polymerizable ethylenic double bond, a reaction product obtained by reaction of (BM1) compound, (BM2) compound and (BM3) compound, wherein (BM1) has in each molecule at least one polymerizable ethylenic double bond and one hydroxyl group, (BM2) has in each molecule one secondary amino group and one hydroxyl group and (BM3) is a diisocyanate compound; and
wherein a molar ratio (R) of a number of moles of (BM1) to a number of moles of (BM2)(a number of moles of the (BM1)/a number of moles of (BM2)) is in the range of 2.4 to 38.0.

2. The photosensitive lithographic printing plate material of claim 1, wherein the molar ratio (R) is in the range of 3.0 to 18.0.

3. The photosensitive lithographic printing plate material of claim 1, wherein (A) polymerization initiator comprises a compound of hexaarylbiimidazole.
